(19) United States
(12) Patent Application Publication
(10) Pub. No.: US 2007/0246736 A1
(43) Pub. Date: Oct. 25, 2007

(54) Light emitting element and communication device using same

(75) Inventors: Masanobu Senda, Aichi-ken (JP); Naoki Arazoe, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI CO., LTD., Aichi-ken (JP)

(21) Appl. No.: 11/785,248

(22) Filed: Apr. 16, 2007

(30) Foreign Application Priority Data
Apr. 14, 2006 (JP) 2006-112115
Feb. 9, 2007 (JP) 2007-031149

(51) Int. Cl. H01L 33/00

(52) U.S. Cl. 257/103

(57) ABSTRACT

A light emitting element has a well layer formed of a GaN-based semiconductor, a barrier layer next to the well layer, the barrier layer being formed of a GaN-based semiconductor, and a GaN-based semiconductor layer formed between the well layer and the barrier layer. The GaN-based semiconductor layer has a dopant to cancel a piezoelectric field caused between the well layer and the barrier layer.

The present application is based on Japanese patent application Nos. 2006-112115 and 2007-031149, the entire contents of which are incorporated herein by reference.

### BACKGROUND OF THE INVENTION

1. Field of the Invention

This invention relates to a light emitting element that a group III nitride-based compound semiconductor layer is formed on a sapphire substrate, and to a communication device using the same.

2. Description of the Related Art

A GaN-based light emitting element is known as one of group III nitride-based compound semiconductor light emitting elements. The GaN-based light emitting element has emission characteristics from a UV region to a visible region. Since emitted light thereof can be combined with a wavelength conversion means such as a phosphor to provide a high-brightness white light, it is a great deal proposed to use the GaN-based light emitting element for a white light source.

Light emitting elements can be also used as a light source for optical communications. Conventionally, a high-brightness light emitting element to emit a red light (630 to 640 nm) is used as an optical communication light source in a light-emitting unit of a communication device such that a light inputted into an optical fiber is received by a light receiving element in a light-receiving unit thereof, or a light transmitted through a space is received by the light receiving element in the light-receiving unit, and the received light is then photoelectric-converted to output a received signal.

Communication optical fibers formed of quartz with a low transmission loss are well known. However, in consideration of price and precision required in its connection work, a POF (plastic optical fiber) attracts attention since it is lower in cost than the quartz and it is easy to employ. The POF has a minimum value in transmission loss at about 570 nm, i.e., the transmission loss in a wavelength band of blue to green lights is smaller than that of the red light. Thus, the light-emitting unit with the GaN-based light emitting element can be well matched to the POF.

When the GaN-based light emitting element is used for the optical communication, the emission intensity and responsiveness of the light emitting element during the operation are important factors in order to have a communication speed equal to or more than that of the red light emitting element. In this regard, it is known that a GaN-based semiconductor causes a piezoelectric field due to the property of a semiconductor layer formed on the sapphire substrate, where in case of forming a quantum well structure, there is pointed out a problem that a band in the quantum well is inclined to promote the spatial separation of electron and hole to cause a reduction in the emission intensity.

JP-A-2005-056973 discloses a method that In composition ratio X and thickness of an In_{X}Ga_{1-X}N quantum well is controlled to enhance the emission intensity.

However, the method of JP-A-2005-056973 has a problem that it is not suited for the high-speed optical communication since it is insufficient in responsiveness required in the communication light emitting element although it can provide a good emission intensity property for general display light emitting elements.

### SUMMARY OF THE INVENTION

It is an object of the invention to provide a light emitting element that can cancel the piezoelectric field due to the element structure to provide an improved match to an optical transmission line.

It is a further object of the invention to provide a communication device using the light emitting element.

(1) According to one embodiment of the invention, a light emitting element comprises:

a well layer comprising a GaN-based semiconductor;

a barrier layer next to the well layer, the barrier layer comprising a GaN-based semiconductor; and

a GaN-based semiconductor layer formed between the well layer and the barrier layer,

wherein the GaN-based semiconductor layer includes a dopant to cancel piezoelectric field caused between the well layer and the barrier layer.

In the above embodiment (1), the following modifications and changes can be made.

(i) The GaN-based semiconductor layer is formed at an interface between the barrier layer and the well layer of a SQW (single-quantum well) structure.

(ii) The GaN-based semiconductor layer is formed at an interface between the barrier layer formed on a side of a p-type layer and the well layer, and the dopant comprises Mg.

(iii) The GaN-based semiconductor layer is formed at an interface between the barrier layer formed on a side of an n-type layer and the well layer, and the dopant comprises Si.

(iv) The GaN-based semiconductor layer comprises a thickness of not less than 1.3 nm.

(v) The GaN-based semiconductor layer comprises a thickness of not less than 2.6 nm and not more than 10 nm.

(vi) The GaN-based semiconductor layer comprises a Si concentration in a range of 2.5×10¹⁸/cm³ to 1.0×10¹⁹/cm³.

(vii) The GaN-based semiconductor layer is formed at an interface between the barrier layer and the well layer of an MQW (multiquantum well) structure.

(viii) The well layer comprises an emission area in a range of 1000 μm² to 22000 μm².

(2) According to another embodiment of the invention, a communication device comprises:

the light emitting element as defined by the above embodiment (1); and

an optical fiber through which to transmit a light emitted from the light emitting element.

In the above embodiment (2), the following modifications and changes can be made.

(ix) The optical fiber comprises a POF (plastic optical fiber) that comprises a minimum transmission loss in a range of an emission wavelength of the light emitting element.

(3) According to another embodiment of the invention, a communication device comprises:

a light-emitting unit comprising the light emitting element as defined by the above embodiment (1); and

a light-receiving unit to receive a visible light emitted from the light-emitting unit.

### BRIEF DESCRIPTION OF THE DRAWINGS

The preferred embodiments according to the invention will be explained below referring to the drawings, wherein:

FIG. 1 is a schematic diagram showing a communication device using a light emitting element in a first preferred embodiment of the invention;

FIG. 2A is a schematic cross sectional view showing the light emitting element of the first embodiment;

FIG. 2B is a partially enlarged cross sectional view showing an SQW (single-quantum well) in FIG. 2A;

FIGS. 3A and 3B illustrate a mechanism for cancelling the piezoelectric field in the light emitting element of the first embodiment, where FIG. 3A is a schematic diagram illustrating the SQW where the piezoelectric field is generated, and FIG. 3B is a schematic diagram illustrating the SQW where an Mg-doped GaN layer is provided;

FIG. 4 is a characteristic diagram showing the responsiveness and optical output of an LED of the first embodiment;

FIG. 5A is a schematic cross sectional view showing a light emitting element in a second preferred embodiment of the invention;

FIG. 5B is a partially enlarged cross sectional view showing an SQW (single-quantum well) in FIG. 5A;

FIGS. 6A and 6B illustrate a mechanism for cancelling the piezoelectric field in the light emitting element of the second embodiment, where FIG. 6A is a schematic diagram illustrating the SQW where the piezoelectric field is generated, and FIG. 6B is a schematic diagram illustrating the SQW where an Si-doped GaN layer is provided;

FIG. 7 is a characteristic diagram showing the responsiveness and optical output of an LED of the second embodiment;

FIG. 8 is a graph showing the relationship between the Si concentration of the Si-doped GaN layer and a rise time/a fall time in an LED of the second embodiment;

FIG. 9 is a graph showing the relationship between the Si concentration of the Si-doped GaN layer and a cutoff frequency in an LED of the second embodiment;

FIG. 10 is a graph showing the relationship between the thickness of the Si-doped GaN layer and a rise time/a fall time in an LED of the second embodiment;

FIG. 11 is a graph showing the relationship between the thickness of the Si-doped GaN layer and a cutoff frequency in an LED of the second embodiment;

FIG. 12A is a schematic cross sectional view showing a light emitting element in a third preferred embodiment of the invention;

FIG. 12B is a partially enlarged cross sectional view showing an SQW (single-quantum well) in FIG. 12A;

FIG. 13A is a schematic cross sectional view showing a light emitting element in a fourth preferred embodiment of the invention;

FIG. 13B is a partially enlarged cross sectional view showing an MQW (multiquantum well) in FIG. 13A; and

FIG. 14 is a schematic diagram showing a communication device using a light emitting element in a fifth preferred embodiment of the invention.

### DETAILED DESCRIPTION OF THE PREFERRED EMBODIMENTS

### First Embodiment

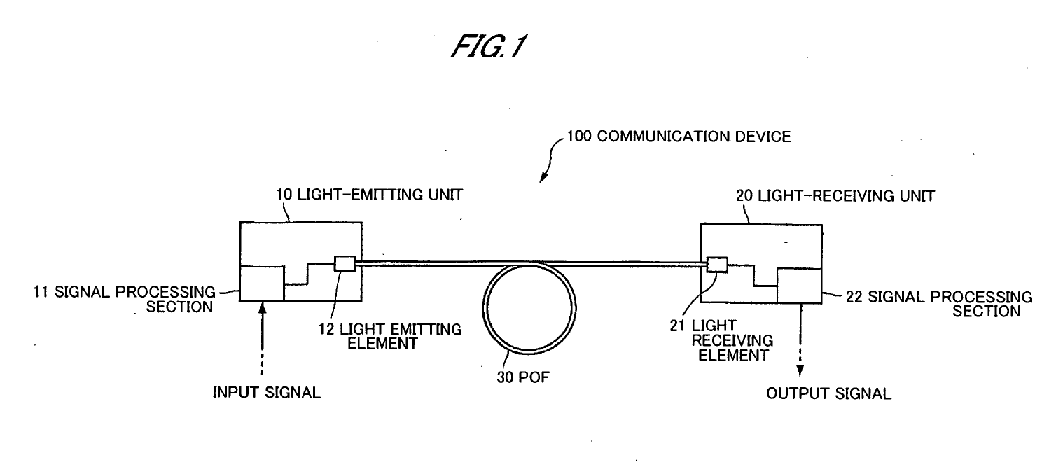

FIG. 1 is a schematic diagram showing a communication device 100 using a light emitting element in the first preferred embodiment of the invention.

The communication device 100 comprises a light-emitting unit 10 for outputting a signal light, a light-receiving unit. 20 for receiving the signal light, and a POF (plastic optical fiber) 30 which is an optical transmission line to connect the light-emitting unit 10 and the light-receiving unit 20 to allow the optical communication therebetween.

The light-emitting unit 10 comprises a signal processing section 11 to which an input signal to be optically transmitted is inputted from outside, a light emitting element 12 which is formed of a GaN-based semiconductor and emits to the POF 30 a light based on the input signal according to a current supplied from the signal processing section 11. The GaN-based semiconductor is represented by a general formula: Al_{X}Ga_{Y}In_{1-X-Y}N (0≦X≦1, 0≦Y≦1, 0≦X+Y≦1) and includes a two-element compound semiconductor such as AlN, GaN and InN, a three-element compound semiconductor such as Al_{X}Ga_{1-X}N, Al_{X}In_{1-X}N and Ga_{X}In_{1-X}N (where 0<X<1).

The light-receiving unit 20 comprises a light-receiving element 21 for receiving the light to be transmitted through the POF 30, and a signal processing section 22 to waveform-process the photoelectric-converted signal to extract a desired output signal.

The POF 30 is formed of a material that is transparent to an emission wavelength of the light emitting element 12. In this embodiment, it is a single-core POF formed of a polymethylmethacrylate (PMMA) resin, and has a feature that its transmission loss is small to the emission wavelength of the GaN-based light emitting element. It may be a multicore POF formed of a similar material.

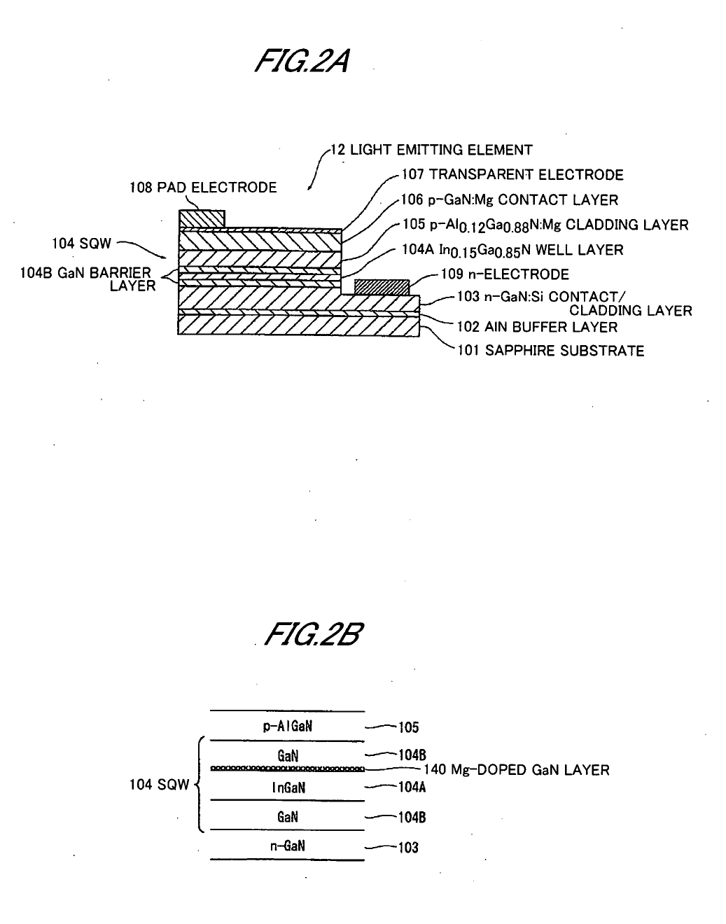

FIG. 2A is a schematic cross sectional view showing the light emitting element of the first embodiment. FIG. 2B is a partially enlarged cross sectional view showing an SQW (single-quantum well) in FIG. 2A. Hereinafter, a portion except a sapphire substrate and an AlN buffer layer is called “light-emitting element portion”.

The light emitting element 12 is a horizontal type of light emitting element where its p-side and n-side electrodes are horizontally disposed. It comprises, sequentially stacked on a sapphire substrate 101 as a growth substrate for growing a group III nitride-based compound semiconductor, an AlN buffer layer 102, an Si-doped n-type GaN:Si contact/cladding layer 103, an SQW 104 with an InGaN/GaN quantum well structure, an Mg-doped p-type Al_{0.12}Ga_{0.88}N:Mg cladding layer 105, an Mg-doped p-type GaN:Mg contact layer 106, and a transparent electrode 107 formed of ITO (indium tin oxide) to spread current into the p-type GaN:Mg contact layer 106. The AlN buffer layer 102 through the p-type GaN:Mg contact layer 106 are formed by MOCVD (metalorganic chemical vapor deposition). The light emitting element 12 has an emission area of 22000 μm², but the emission area is preferably smaller than this and the emission area is preferably not less than 1000 μm². The optical output increases as the emission area increases, while the responsiveness is enhanced as the emission area decreases. Therefore, the emission area is desirably not less than 1000 μm² and not more than 22000 μm² so as to provide the light emitting element with a good responsiveness and a high optical output.

A pad electrode 108 of Au is formed on the surface of the transparent electrode 107. An n-side electrode 109 of Al is formed on the surface of the n-type GaN:Si contact/cladding layer 103 to be exposed by removing a part of the p-type GaN:Mg contact layer 106 through the n-type GaN:Si contact/cladding layer 103 by etching.

The AlN buffer layer 102 is formed by supplying TMG (trimethylgallium), TMA (trimethylaluminum) and an H₂ carrier gas into a reactor in which the sapphire substrate 101 is placed.

The n-type GaN:Si contact/cladding layer 103 is formed about 4 μm thick on the AlN buffer layer 102 by supplying TMG, NH₃ and the H₂ carrier gas into the reactor in which the sapphire substrate 101 is placed, while using as an Si source monosilane (═SiH₄) which is a dopant for providing the n-type conductivity.

The SQW 104 is formed by supplying TMI (trimethylindium), TMG, NH₃ and the H₂ carrier gas into the reactor. TMI, TMG and NH₃ are supplied to form the In_{0.15}Ga_{0.85}N well layer 104A, and TMG and NH₃ are supplied to form the GaN barrier layer 104B. The In_{0.15}Ga_{0.85}N well layer 104A is desirably 1.0 to 4.0 nm in average thickness in consideration of the responsiveness and optical output.

In forming the GaN barrier layer 104B on the p-type layer side, as shown in FIG. 2B, an Mg-doped GaN layer 140 serving as an evaporation preventing protective layer for In and a strain reducing layer as mentioned later is formed 3 nm thick by supplying TMG and NH₃ as well as cyclopentadienyl magnesium (Cp₂Mg) as an Mg source (dopant).

The p-type Al_{0.12}Ga_{0.88}N:Mg cladding layer 105 is formed by supplying NH₃, TMG, TMA and H₂ carrier gas as well as the Cp₂Mg as an Mg source (dopant) into the reactor in which the sapphire substrate 101 is placed.

The p-type GaN contact layer 106 is formed by supplying NH₃, TMG and H₂ carrier gas as well as the Cp₂Mg as an Mg source (dopant) into the reactor in which the sapphire substrate 101 is placed.

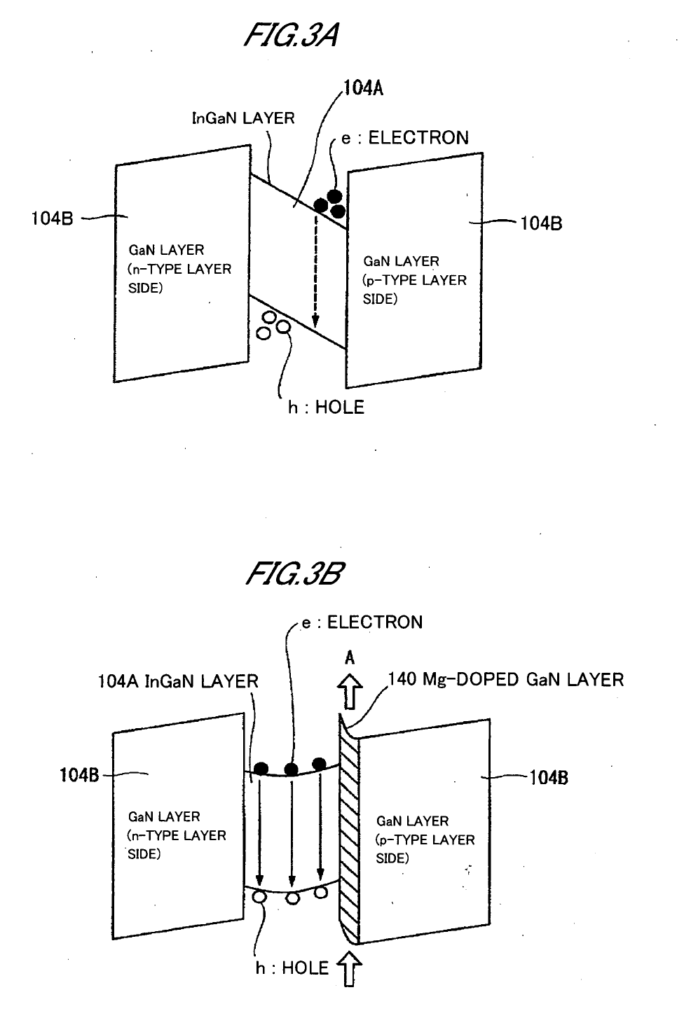

FIGS. 3A and 3B illustrate a mechanism for cancelling the piezoelectric field in the light emitting element of the first embodiment, where FIG. 3A is a schematic diagram illustrating the SQW where the piezoelectric field is generated, and FIG. 3B is a schematic diagram illustrating the SQW where an Mg-doped GaN layer is provided;

As shown in FIG. 3A, when the InGaN layer (═In_{0.15}Ga_{0.85}N well layer) 104A is formed on the GaN layer 104B next to the n-type layer (i.e., adjacent to the n-type layer 103) and the other GaN layer 104B is formed thereon, the piezoelectric field causes an inclination in the band of the InGaN layer 104A, whereby electron e and hole h are separate spatially. In this state, the lifetime of the electron e and hole h lengthens.

In consideration of this, as shown in FIG. 3B, by forming the Mg-doped GaN layer 140 at the interface between the InGaN layer 104A and the GaN barrier layer 104B next to the p-type layer, the strain of the semiconductor layer causing the band inclination can be reduced in the direction of A (i.e., arrowed direction in FIG. 3B). Thus, the layer composition is as follows: undoped GaN barrier layer 104B/undoped InGaN well layer 104A/Mg-doped GaN layer 140/undoped GaN barrier layer 104B/p-type layer 105. This allows the spatial overlapping of electron e and hole h, whereby the lifetime of the electron e and hole h shortens.

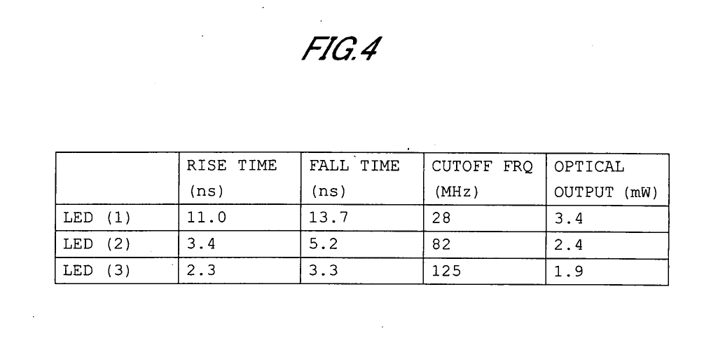

FIG. 4 is a characteristic diagram showing the responsiveness and optical output of an LED of the first embodiment. In FIG. 4, comparisons are made among an LED (1) as a general display LED (with a light-emitting layer formed of MQW (multiquantum well)), an LED (2) with a single light-emitting layer, and an LED (3) with the SQW and the Mg-doped GaN layer 140 of the embodiment.

With regard to the LED (1), the optical output is 3.4 W, the highest among them since it has the MQW light-emitting layer. However, the rise time and fall time are long and the cutoff frequency affecting the communication speed is low. Therefore, it is difficult to use it as a light source to conduct the high-speed optical communication. Herein, the rise time is defined as a time required in reaching 90% from 10% of a steady-state value in pulse response of current density, and the fall, time is defined as a time required in reaching 10% from 90% of a steady-state value. The cutoff frequency fc is calculated by the formula:
fc=(0.35/((tr+tf)/2)×1000
where tr is the rise time and tf is the fall time.

With regard to the LED (2), the communication response characteristics are enhanced since it has the single light-emitting layer as compared to the MQW light-emitting layer of the LED (1). However, the optical output of the LED (2) decreases as compared to the MQW.

With regard to the LED (3), the rise time and fall time are shortened and the cutoff frequency is high. Thus, the optical response speed can be enhanced.

### Effects of the First Embodiment

In the first embodiment, the Mg-doped GaN layer 140 is formed at the interface between the InGaN well layer 104A and the GaN barrier layer 104B next to the p-type layer in order to cancel the piezoelectric field caused in the GaN-based semiconductor layer. Thus, the piezoelectric field causing the band inclination can be canceled to enhance the optical response speed.

Although in the first embodiment the Mg-doped GaN layer 140 is formed to cancel the piezoelectric field, other dopants than the Mg may be used such as Ca and Be. Further, other GaN-based semiconductor layer such as AlGaN, InGaN and AlInGaN may be used instead of the GaN. However, the GaN is preferably used in terms of easiness in controlling the band by the doping of Mg.

Although in the first embodiment the Mg-doped GaN layer 140 is formed on the side of the GaN barrier layer 104B next to the p-type layer in order to cancel the piezoelectric field, a layer to cancel the piezoelectric field may be formed on the side of the GaN barrier layer 104B next to the n-type layer.

### Second Embodiment

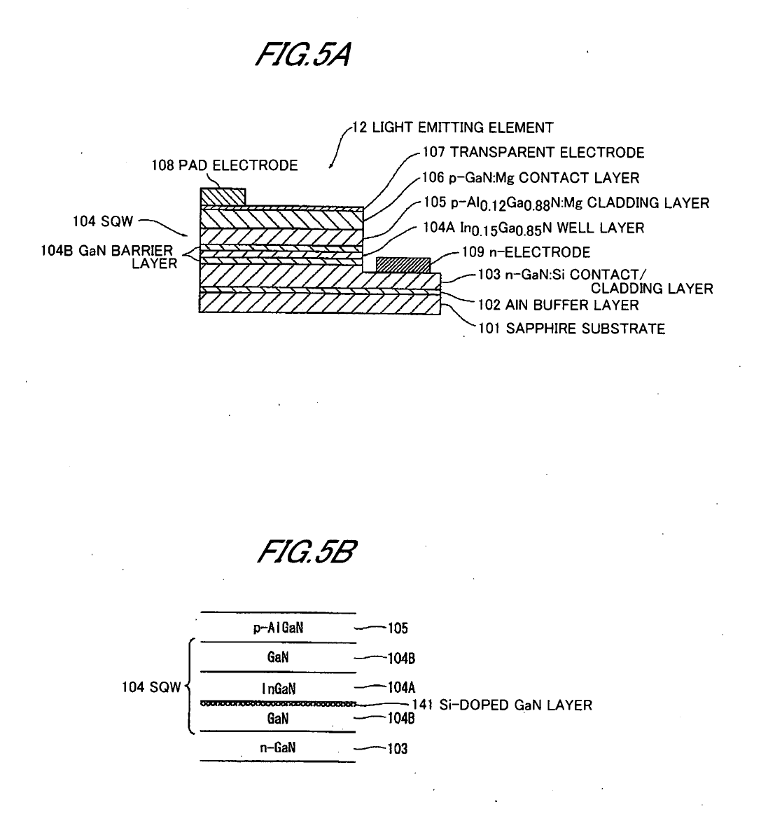

FIG. 5A is a schematic cross sectional view showing a light emitting element in the second preferred embodiment of the invention. FIG. 5B is a partially enlarged cross sectional view showing an SQW (single-quantum well) in FIG. 5A.

The light emitting element 12 of the second embodiment is different from that of the first embodiment in that an Si-doped GaN layer 141 is, as shown in FIG. 5B, formed 7 nm thick in the GaN barrier layer 104B at the interface between the In_{0.15}Ga_{0.84}N well layer 104A and the GaN barrier layer 104B next to the n-type GaN layer 103 in the SQW 104.

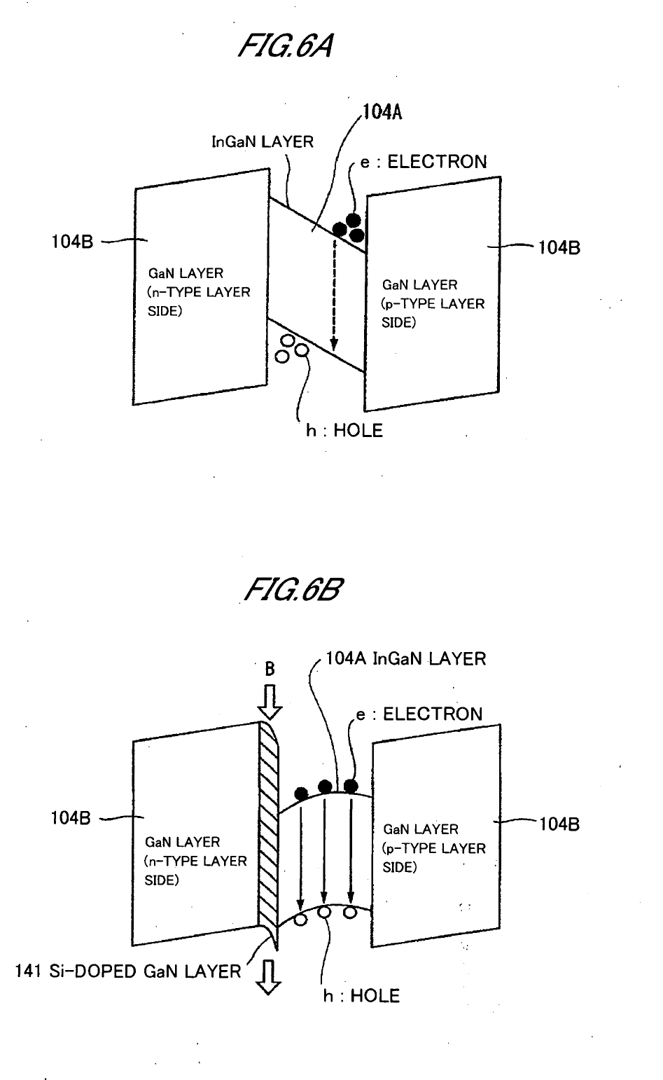

FIGS. 6A and 6B illustrate a mechanism for cancelling the piezoelectric field in the light emitting element of the second embodiment, where FIG. 6A is a schematic diagram illustrating the SQW where the piezoelectric field is generated, and FIG. 6B is a schematic diagram illustrating the SQW where an Si-doped GaN layer is provided.

As shown in FIG. 6A, when the InGaN layer (═In_{0.15}Ga_{0.85}N well layer) 104A is formed on the GaN layer 104B next to the n-type layer and the other GaN layer 104B (which is next to the p-type layer 105) is formed thereon, the piezoelectric field causes an inclination in the band of the InGaN layer 104A, whereby electron e and hole h are separate spatially. In this state, the lifetime of the electron e and hole h lengthens.

In consideration of this, as shown in FIG. 6B, by forming the Si-doped GaN layer 141 at the interface between the InGaN layer 104A and the GaN barrier layer 104B next to the n-type layer 103, the strain of the semiconductor layer causing the band inclination can be reduced in the direction of B (i.e., arrowed direction in FIG. 6B). Thus, the layer composition is as follows: n-type layer 103/undoped GaN barrier layer 104B/Si-doped GaN layer 141/undoped InGaN well layer 104A/undoped GaN barrier layer 104B/p-type layer 105. This allows the spatial overlapping of electron e and hole h, whereby the lifetime of the electron e and hole h shortens.

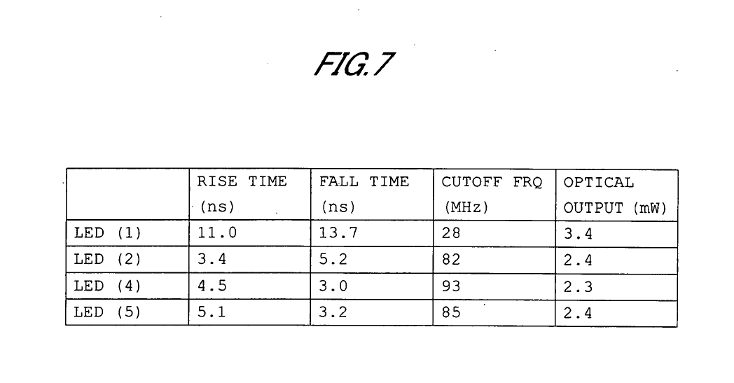

FIG. 7 is a characteristic diagram showing the responsiveness and optical output of an LED of the second embodiment. In FIG. 7, comparisons are made among the LED (1) as a general display LED (with a light-emitting layer formed of MQW (multiquantum well)), the LED (2) with a single light-emitting layer, and LED's (4) and (5) with the SQW and the Si-doped GaN layer 141 of the embodiment. The LED (4) is, as shown in FIG. 5B, composed of p-AlGaN 105 (i.e., p-Al_{0.12}Ga_{0.88}N)/GaN 104B/InGaN 104A/Si-doped GaN layer 141/GaN 104B/n-GaN 103. The LED (5) is different from the LED (4) in that the p-type barrier layer is formed of Al_{0.05}Ga_{0.95}N.

With regard to the LED's (1) and (2), results thereof are the same as explained earlier in the first embodiment and explanations thereof are omitted here. With regard to the LED's (4) and (5), by forming the Si-doped GaN layer 141, the fall time is shortened and the cutoff frequency is high to enhance the optical response speed. The optical outputs thereof are the same as the LED (2).

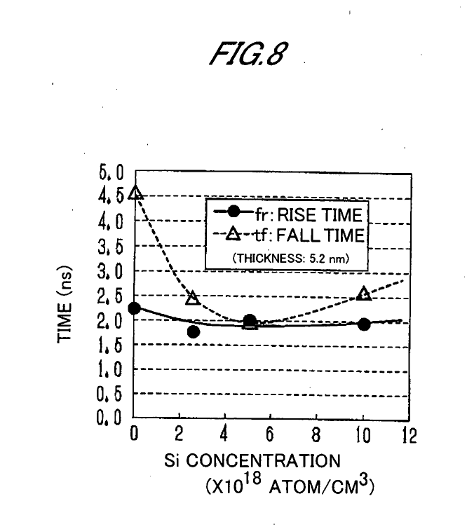

FIG. 8 is a graph showing the relationship between the Si concentration of the Si-doped GaN layer and the rise time/fall time in the LED of the second embodiment.

For example, the Si-doped GaN layer 141 is set to be 5.2 nm in thickness, and the rise/fall times thereof are measured according as the Si concentration changes.

As shown in FIG. 8, when the Si concentration of the Si-doped GaN layer 141 is in the range of 2.5×10¹⁸/cm³ to 1.0×10¹⁹/cm³, the fall time becomes 2.5 ns or less. Thus, since the fall time can be controlled to be not more than 2.5 ns, the communication speed can be enhanced. Furthermore, error in the fall time can be advantageously reduced.

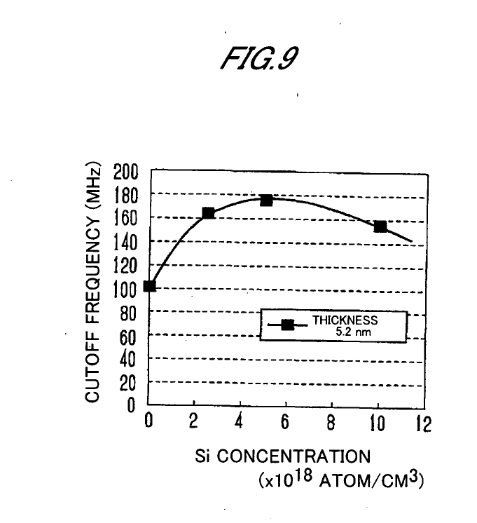

FIG. 9 is a graph showing the relationship between the Si concentration of the Si-doped GaN layer 141 and the cutoff frequency in the LED of the second embodiment. The cutoff frequency is calculated from the rise and fall times measured previously as in FIG. 8, where the Si-doped GaN layer 141 is set to be 5.2 nm in thickness.

As shown in FIG. 9, when the Si concentration of the Si-doped GaN layer 141 is in the range of 2.5×10¹⁸/cm³ to 1.0×10¹⁹/cm³, the cutoff frequency becomes 150 MHz or more. Thus, since the cutoff frequency can be controlled to be not less than 150 MHz, the communication speed can be enhanced.

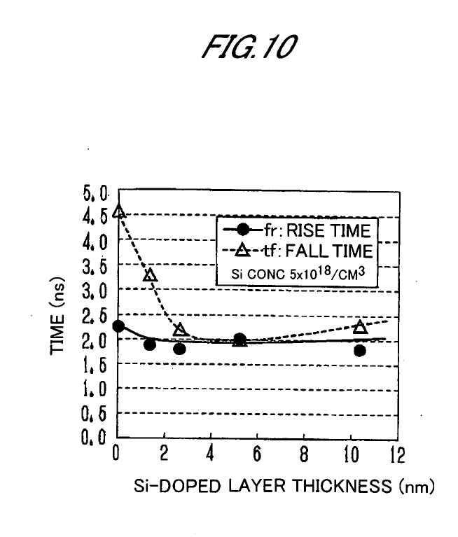

FIG. 10 is a graph showing the relationship between the thickness of the Si-doped GaN layer and the rise time/fall time in the LED of the second embodiment.

For example, the Si-doped GaN layer 141 is set to be 5.0×10¹⁸/cm³ in Si concentration, and the rise/fall times thereof are measured according as the thickness of the Si-doped GaN layer 141 changes.

As shown in FIG. 10, when the thickness of the Si-doped GaN layer 141 is 1.3 nm or more, the fall time becomes 3.5 ns or less. Thus, since the fall time can be controlled to be not more than 3.5 ns, the communication speed can be enhanced. Furthermore, error in the fall time can be advantageously reduced.

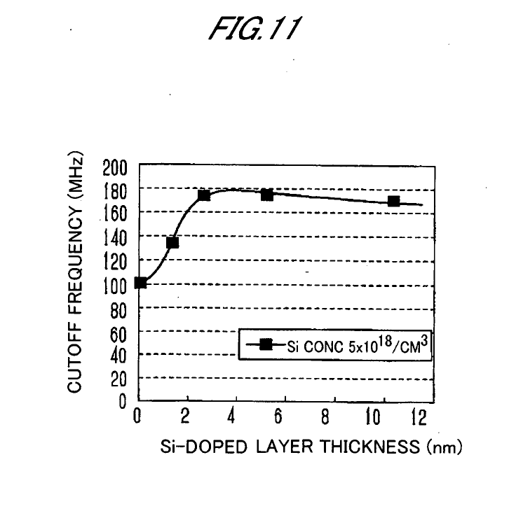

FIG. 11 is a graph showing the relationship between the thickness of the Si-doped GaN layer and the cutoff frequency in the LED of the second embodiment.

As shown in FIG. 11, when the thickness of the Si-doped GaN layer 141 is in the range of 2.6 nm to 10 nm, the cutoff frequency becomes 170 MHz or more. Thus, since the cutoff frequency can be controlled to be not less than 170 MHz, the communication speed can be enhanced.

### Effects of the Second Embodiment

In the second embodiment, the Si-doped GaN layer 141 is formed at the interface between the InGaN well layer 104A and the GaN barrier layer 104B next to the n-type layer in order to cancel the piezoelectric field caused in the GaN-based semiconductor layer. Thus, the piezoelectric field causing the band inclination can be canceled to enhance the optical response speed.

Although in the second embodiment the Si-doped GaN layer 141 is formed to cancel the piezoelectric field, other dopants than the Si may be used such as Ge and C. Further, other GaN-based semiconductor layer such as AlGaN, InGaN and AlInGaN may be used instead of the GaN. However, the GaN is preferably used in terms of easiness in controlling the band by the doping of Si.

### Third Embodiment

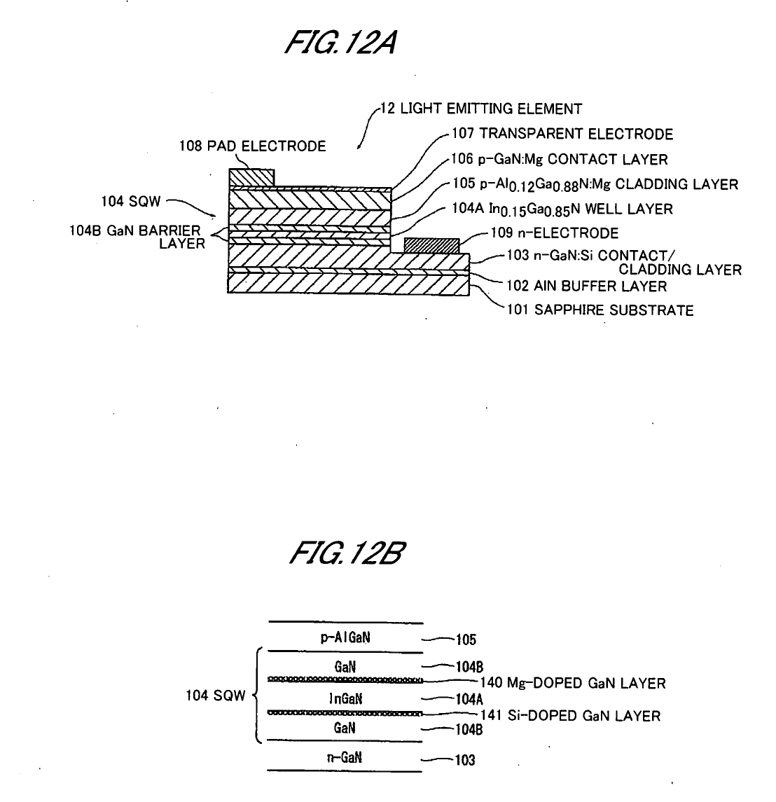

FIG. 12A is a schematic cross sectional view showing a light emitting element in the third preferred embodiment of the invention. FIG. 12B is a partially enlarged cross sectional view showing an SQW (single-quantum well) in FIG. 12A.

The light emitting element 12 of the third embodiment is different from that of the first embodiment in that, in the SQW 104 as shown in FIG. 12B, the Mg-doped GaN layer 140 is formed 3 nm thick in the GaN barrier layer 104B at the interface between the In_{0.15}Ga_{0.85}N well layer 104A and the GaN barrier layer 104B next to the p-type AlGaN layer 105, and the Si-doped GaN layer 141 is formed 3 nm thick in the GaN barrier layer 104B at the interface between the In_{0.15}Ga_{0.85}N well layer 104A and the GaN barrier layer 104B next to the n-type GaN layer 103.

### Effects of the Third Embodiment

In the third embodiment, the Mg-doped GaN layer 140 is formed at the interface between the InGaN well layer 104A and the GaN barrier layer 104B next to the p-type layer, and the Si-doped GaN layer 141 is formed at the interface between the InGaN well layer 104A and the GaN barrier layer 104B next to the n-type layer in order to cancel the piezoelectric field caused in the GaN-based semiconductor layer. Thus, the piezoelectric field causing the band inclination can be further completely canceled to enhance the optical response speed.

Although in the above embodiments the light-emitting layer is formed of the SQW, the invention can be also applied to an MQW (multiquantum well).

### Fourth Embodiment

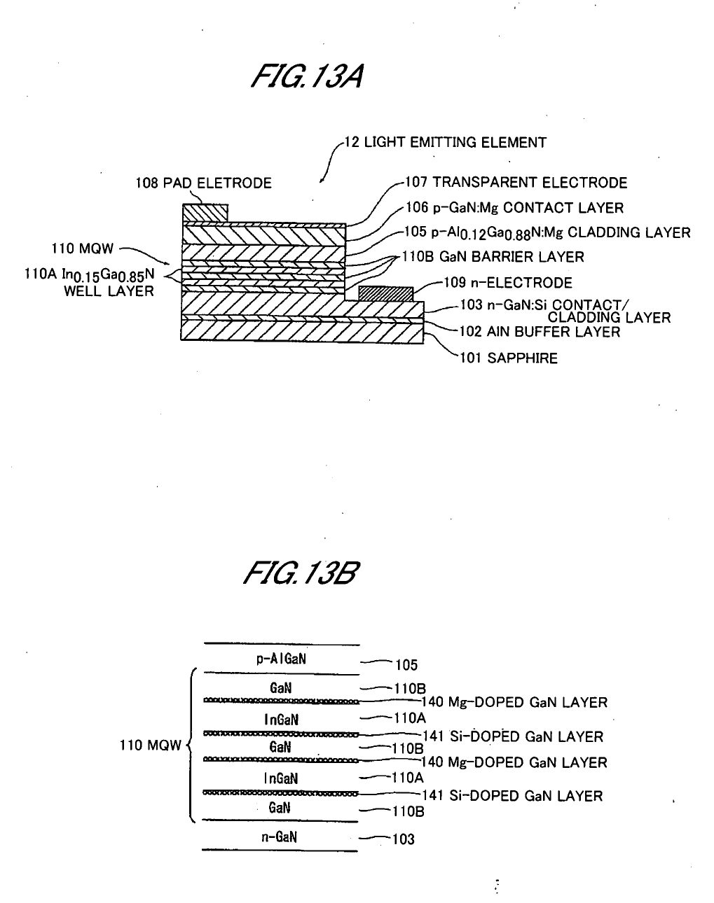

FIG. 13A is a schematic cross sectional view showing a light emitting element in the fourth preferred embodiment of the invention. FIG. 13B is a partially enlarged cross sectional view showing an MQW (multiquantum well) in FIG. 13A.

The light emitting element 12 of the fourth embodiment is formed by applying the same composition as the third embodiment to the MQW other the SQW. It is different from that of the third embodiment in that, in the MQW 110 as shown in FIG. 12B, the Mg-doped GaN layer 140 is formed 3 nm thick in the GaN barrier layer 110B at the interface between the In_{0.15}Ga_{0.5}N well layer 110A and the GaN barrier layer 110B next to on the p-type layer side, and the Si-doped GaN layer 141 is formed 3 nm thick in the GaN barrier layer 110B at the interface between the In_{0.15}Ga_{0.85}N well layer 110A and the GaN barrier layer 110B next to on the n-type layer side.

### Effects of the Fourth Embodiment

In the fourth embodiment, adding to the effects of the third embodiment, the light emitting element 12 can have an optical output enhanced by the MQW.

### Fifth Embodiment

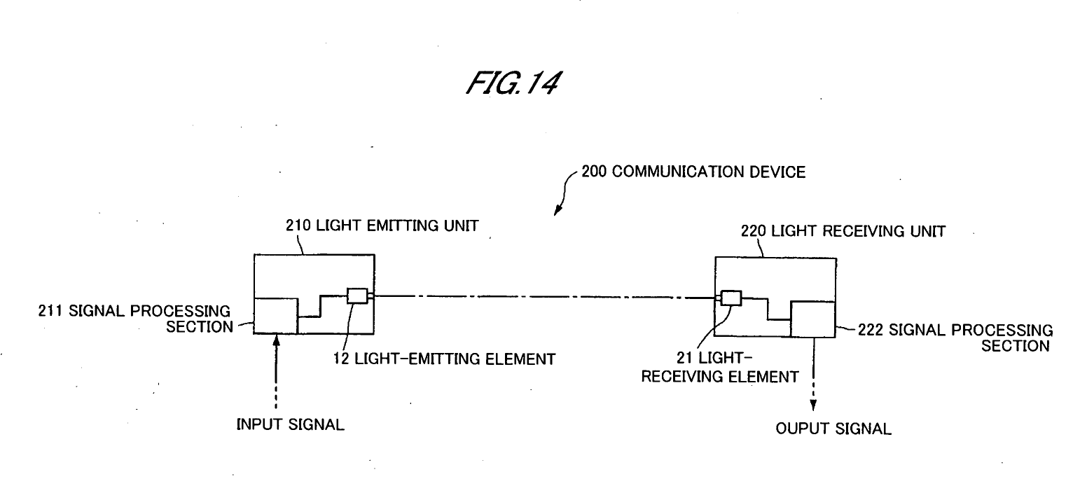

FIG. 14 is a schematic diagram showing a communication device 200 using a light emitting element in the fifth preferred embodiment of the invention.

As shown in FIG. 14, the communication device 200 comprises a light-emitting unit 210 for outputting a signal light, and a light-receiving unit 20 for receiving the signal light. For example, the communication device 200 can be applied to a remote controller for home electric appliances etc.

The light-emitting unit 210 comprises a signal processing section 211 to which an input signal to be optically transmitted is inputted from outside, the light emitting element 12 which is formed of a GaN-based semiconductor and emits through space toward the light-receiving unit 220 a light based on the input signal according to a current supplied from the signal processing section 211. Meanwhile, the light emitting element 12 is the same as in the first embodiment and explanations thereof are omitted here.

The light-receiving unit 220 comprises a light-receiving element 21 for receiving the light to be transmitted through space, and a signal processing section 222 to waveform-process the photoelectric-converted signal to extract a desired output signal.

### Effects of the Fifth Embodiment

Also in the fifth embodiment, the Mg-doped GaN layer 140 is formed at the interface between the InGaN well layer 104A and the GaN barrier layer 104B next to the p-type layer in order to cancel the piezoelectric field caused in the GaN-based semiconductor layer. Thus, the piezoelectric field causing the band inclination can be canceled to enhance the optical response speed.

Furthermore, since the light emitting element 12 emits a visible light, whether the communication is in action or not can be confirmed by human eyes. Especially, since the light emitting element 12 is formed of the GaN-based semiconductor layer to emit blue to green light, the human eyes can clearly perceive it. Further, since the optical output thereof can be higher than the optical communication LED to emit red light, long-distance communication can be achieved. In case of infrared communication, there are problems that the communication speed is as low as about 1 to 100 Mbps, and whether the communication is in action or not cannot be confirmed by the human eyes since it is not a visible light. In case of red light, since the optical output is as low as about 1 mW, a spatial distance available for the communication is only several centimeters and not practical.

As such, the communication device 200 of the embodiment can be cancel the piezoelectric field caused by the structure of the light emitting element, and can also use the communication signal light as a light for confirming the operation of the device.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A light emitting element, comprising:
a well layer comprising a GaN-based semiconductor;
a barrier layer next to the well layer, the barrier layer comprising a GaN-based semiconductor; and
a GaN-based semiconductor layer formed between the well layer and the barrier layer,
wherein the GaN-based semiconductor layer includes a dopant to cancel piezoelectric field caused between the well layer and the barrier layer.

2. The light emitting element according to claim 1, wherein:
the GaN-based semiconductor layer is formed at an interface between the barrier layer and the well layer of a SQW (single-quantum well) structure.

3. The light emitting element according to claim 1, wherein:
the GaN-based semiconductor layer is formed at an interface between the barrier layer formed on a side of a p-type layer and the well layer, and
the dopant comprises Mg.

4. The light emitting element according to claim 1, wherein:
the GaN-based semiconductor layer is formed at an interface between the barrier layer formed on a side of an n-type layer and the well layer, and
the dopant comprises Si.

5. The light emitting element according to claim 4, wherein:
the GaN-based semiconductor layer comprises a thickness of not less than 1.3 nm.

6. The light emitting element according to claim 4, wherein:
the GaN-based semiconductor layer comprises a thickness of not less than 2.6 nm and not more than 10 nm.

7. The light emitting element according to claim 4, wherein:
the GaN-based semiconductor layer comprises a Si concentration in a range of 2.5×10¹⁸/cm³ to 1.0×10¹⁹/cm³.

8. The light emitting element according to claim 1, wherein:
the GaN-based semiconductor layer is formed at an interface between the barrier layer and the well layer of an MQW (multiquantum well) structure.

9. The light emitting element according to claim 1, wherein:
the well layer comprises an emission area in a range of 1000 μm² to 22000 μm².

10. A communication device, comprising:
the light emitting element as defined by claim 1; and
an optical fiber through which to transmit alight emitted from the light emitting element.

11. The communication device according to claim 10, wherein:
the optical fiber comprises a POF (plastic optical fiber) that comprises a minimum transmission loss in a range of an emission wavelength of the light emitting element.

12. A communication device, comprising:
a light-emitting unit comprising the light emitting element as defined by claim 1; and
a light-receiving unit to receive a visible light emitted from the light-emitting unit.
